(19) United States
(12) Patent Application Publication
(10) Pub. No.: US 2025/0006636 A1
(43) Pub. Date: Jan. 2, 2025

(54) SEMICONDUCTOR MEMORY DEVICES

(71) Applicant: SAMSUNG ELECTRONICS CO., LTD., Suwon-si (KR)

(72) Inventors: Gwang Guk AN, Suwon-si (KR); Jun Ho SONG, Suwon-si (KR); Zhe WU, Suwon-si (KR); So Yeon CHOI, Suwon-si (KR)

(21) Appl. No.: 18/651,142

(22) Filed: Apr. 30, 2024

(30) Foreign Application Priority Data
Jun. 29, 2023 (KR) 10-2023-0084026

(51) Int. Cl. H01L 23/528; H10B 63/00; H10N 70/00

(52) U.S. Cl. CPC H01L 23/5283; H10B 63/84; H10N 70/841; H10N 70/8825; H10N 70/8828

(57) ABSTRACT

A semiconductor memory device comprising: a substrate extending in a first direction and a second direction; first conductive lines extending in the first direction on the substrate; first insulating structures that are alternately arranged with the first conductive lines in the second direction, wherein the first insulating structures extend in a third direction intersecting the first direction and the second direction; first information storage films on the first conductive lines and the first insulating structures; and second conductive lines extending in the second direction on the first information storage films, wherein the first information storage films include first regions that overlap the first conductive lines in the third direction and second regions that overlap the first insulating structures in the third direction, and a first height of upper surfaces of the first regions is different from a second height of upper surfaces of the second regions.

### CROSS-REFERENCE TO RELATED APPLICATION

This application claims priority from Korean Patent Application No. 10-2023-0084026 filed on Jun. 29, 2023 in the Korean Intellectual Property Office, and all the benefits accruing therefrom under 35 U.S.C. 119, the contents of which in its entirety are herein incorporated by reference.

### BACKGROUND

The present disclosure relates to semiconductor memory devices.

Semiconductor memory devices may be classified into volatile memory devices, such as a static random-access memory (SRAM), a dynamic random-access memory (DRAM), or a synchronous DRAM (SDRAM), which lose the stored data when the power supply is interrupted, and non-volatile memory devices, such as a read-only memory (ROM), a programmable ROM (PROM), an electrically programmable ROM (EPROM), an electrically erasable and programmable ROM (EEPROM), a flash memory device, a phase-change random-access memory (PRAM), a magnetic random-access memory (MRAM), a resistive random-access memory (RRAM), a ferroelectric random-access memory (FRAM), which retain the stored data even when the power supply is interrupted.

Recently, research utilizing chalcogenide-based materials with a threshold voltage, aimed at improving the performance of semiconductor memory devices, has been actively conducted.

### SUMMARY

Aspects of the present disclosure may provide semiconductor memory devices with improved performance and reliability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a semiconductor memory device includes: a substrate that extends in a first direction and a second direction, wherein the first direction and the second direction intersect each other; first conductive lines that extend in the first direction on the substrate; first insulating structures that are alternately arranged with the first conductive lines in the second direction, wherein the first insulating structures extend in a third direction that intersects the first direction and the second direction; first information storage films on the first conductive lines and the first insulating structures; and second conductive lines that extend in the second direction on the first information storage films, wherein the first direction and the second direction are parallel with an upper surface of the substrate, the third direction is perpendicular to the upper surface of the substrate, the first information storage films include first regions that overlap the first conductive lines in the third direction, and second regions that overlap the first insulating structures in the third direction, and a first height of upper surfaces of the first regions is different from a second height of upper surfaces of the second regions.

According to an aspect of the present disclosure, a semiconductor memory device includes: a substrate that extends in a first direction and a second direction, wherein the first direction and the second direction intersect each other; first conductive lines that extend in the first direction on the substrate; first insulating structures that are alternately arranged with the first conductive lines in the second direction, wherein the first insulating structures extend in a third direction that intersects the first direction and the second direction; first information storage films on the first conductive lines and the first insulating structures; second conductive lines that extend in the second direction on the first information storage films; and second insulating structures that are alternately arranged with the second conductive lines in the first direction, wherein the second insulating structures extend into the first information storage films in the third direction, wherein the first direction and the second direction are parallel with an upper surface of the substrate, the third direction is perpendicular to the upper surface of the substrate, a first height of upper surfaces of the first information storage films that overlap the first conductive lines in the third direction is different from a second height of upper surfaces of the first information storage films that overlap the first insulating structures in the third direction, and the first information storage films continuously extend in the second direction, and are separated by the second insulating structures in the first direction.

According to an aspect of the present disclosure, a semiconductor memory device includes: a substrate that extends in a first direction and a second direction, wherein the first direction and the second direction intersect each other; first conductive lines that extend in the first direction on the substrate; first insulating structures that are alternately arranged with the first conductive lines in the second direction, wherein the first insulating structures extend in a third direction that intersects the first direction and the second direction; first information storage films on the first conductive lines and the first insulating structures; second conductive lines that extend in the second direction on the first information storage films; second insulating structures that are alternately arranged with the second conductive lines in the first direction, wherein the second insulating structures extend into the first information storage films in the third direction; second information storage films on the second conductive lines and the second insulating structures, wherein the second information storage films extend in the first direction and are spaced apart from one another in the second direction; third conductive lines that extend in the first direction on the second information storage films; and third insulating structures that are alternately arranged with the third conductive lines in the second direction and extend into the third conductive lines and the second information storage films, wherein the first direction and the second direction are parallel with an upper surface of the substrate, the third direction is perpendicular to the upper surface of the substrate, first steps are disposed between upper surfaces of the first conductive lines and upper surfaces of the first insulating structures, and the first insulating structures partially extend into the first information storage films in the third direction.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail embodiments thereof with reference to the attached drawings, in which:

FIG. 1 is a block diagram of a semiconductor memory device according to some embodiments of the present disclosure;

FIG. 2 is a perspective view of a semiconductor memory device according to some embodiments of the present disclosure;

FIGS. 3, 4, and 5 are cross-sectional views taken along lines A-A′, B-B′, and C-C′ of FIG. 2, respectively;

FIGS. 6 and 7 are cross-sectional views taken along lines X1-X1′ and Y1-Y1′ of FIG. 2, respectively;

FIGS. 8 and 9 are cross-sectional views of a semiconductor memory device according to some embodiments of the present disclosure;

FIGS. 10 and 11 are cross-sectional views of a semiconductor memory device according to some embodiments of the present disclosure;

FIG. 12 is a perspective view of a semiconductor memory device according to some embodiments of the present disclosure;

FIGS. 13 and 14 are cross-sectional views taken along lines X2-X2′ and Y2-Y2′ of FIG. 12, respectively;

FIG. 15 is a perspective view of a semiconductor memory device according to some embodiments of the present disclosure;

FIGS. 16 and 17 are cross-sectional views taken along lines X3-X3′ and Y3-Y3′ of FIG. 15, respectively; and

FIGS. 18 through 28 are perspective or cross-sectional views illustrating intermediate steps of a method of fabricating a semiconductor memory device according to some embodiments of the present disclosure.

### DETAILED DESCRIPTION

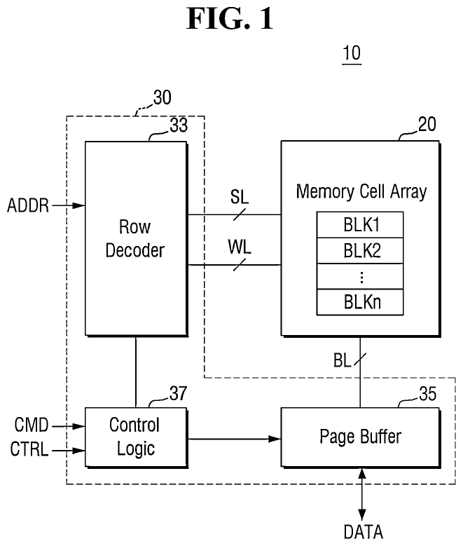

A semiconductor memory device according to some embodiments of the present disclosure will be described with reference to FIGS. 1 through 7.

It should be understood that the terms “first,” “second,” “third,” etc., used herein to describe various elements, components, regions, layers, and/or sections are employed for the purpose of distinguishing one element, component, region, layer, or section from another. Therefore, a first element, component, region, layer, or section described below could also be referred to as a second element, component, region, layer, or section, without deviating from the essence and scope of the present disclosure.

As used herein, the singular forms “a,” “an,” and “the” are intended to include the plural forms as well, unless the context clearly indicates otherwise.

FIG. 1 is a block diagram of a semiconductor memory device according to some embodiments of the present disclosure.

Referring to FIG. 1, a semiconductor memory device 10 includes a memory cell array 20 and a peripheral circuit 30.

The memory cell array 20 may include a plurality of memory cell blocks BLK1 through BLKn. Each of the plurality of memory cell blocks BLK1 through BLKn may include a plurality of memory cells. The memory cell array 20 may be connected (e.g., electrically connected) to the peripheral circuit 30 through bitlines BL, wordlines WL, and/or selection lines SL. Specifically, the plurality of memory cell blocks BLK1 through BLKn may be connected (e.g., electrically connected) to a row decoder 33 through the wordlines WL and the selection lines SL. The plurality of memory cell blocks BLK1 through BLKn may be connected (e.g., electrically connected) to a page buffer 35 through the bitlines BL. It will be understood that when an element or layer is referred to as being “connected to”, or “coupled to” another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection.

The peripheral circuit 30 may receive an address ADDR, commands CMD, and control signals CTRL from outside the semiconductor memory device 10 and may exchange data DATA with an external device outside the semiconductor memory device 10. The peripheral circuit 30 may include the row decoder 33, the page buffer 35, and a control logic 37. Although not specifically depicted, the peripheral circuit 30 may further include various sub-circuits such as an input/output circuit, a voltage generation circuit for generating voltages necessary for the operation of the semiconductor memory device 10, and an error correction circuit for correcting error in data “DATA” read from the memory cell array 20. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

The control logic 37 may be connected (e.g., electrically connected) to the row decoder 33, the page buffer 35, the input/output circuit, and/or the voltage generation circuit. The control logic 37 may control the general operation of the semiconductor memory device 10. The control logic 37 may generate various inner control signals for use in the semiconductor memory device 10 in response to the control signals CTRL. For example, the control logic 37 may control the voltages provided to the wordlines WL and the bitlines BL during a memory operation such as a program operation or an erase operation.

The row decoder 33 may select at least one of the plurality of memory cell blocks BLK1 through BLKn in response to the address ADDR and may select at least one of the wordlines WL and at least one of the selection lines SL of the selected memory cell block(s) among the plurality of memory cell blocks BLK1 through BLKn. Also, the row decoder 33 may transmit voltages for performing memory operations to the (selected) wordline(s) WL of the selected memory cell block(s).

The page buffer 35 may be connected (e.g., electrically connected) to the memory cell array 20 via the bitlines BL. The page buffer 35 may function as a write driver or a sense amplifier. Specifically, during a program operation, the page buffer 35 may function as a write driver and may apply a voltage corresponding to data “DATA” to be stored in the memory cell array 20 through the bitlines BL. Conversely, during a read operation, the page buffer 35 may function as a sense amplifier and may senses data “DATA” stored in the memory cell array 20.

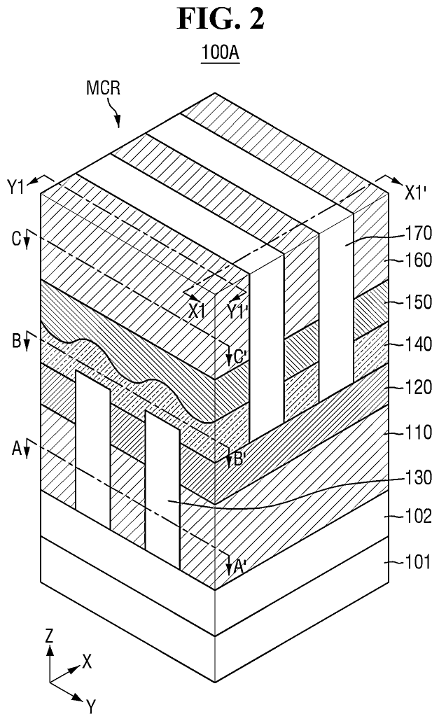

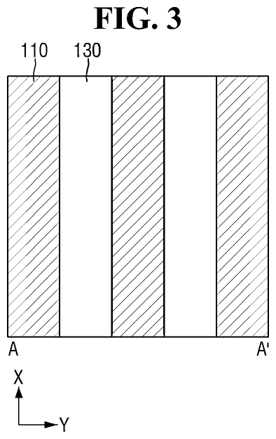

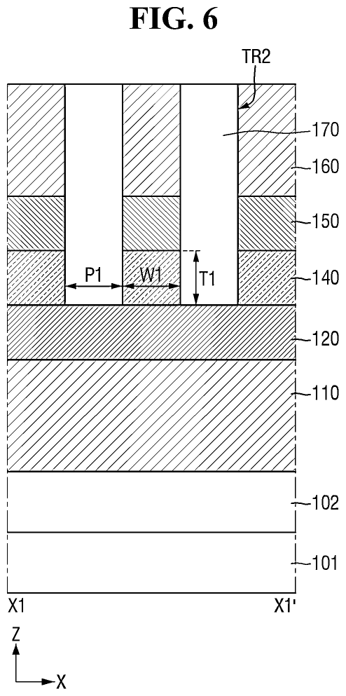

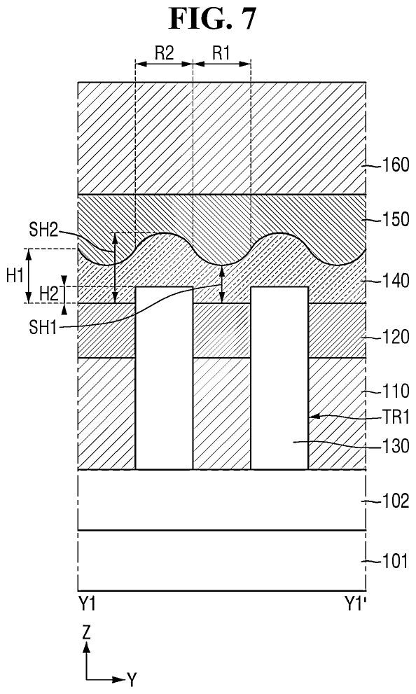

FIG. 2 is a perspective view of a semiconductor memory device according to some embodiments of the present disclosure. FIGS. 3, 4, and 5 are cross-sectional views taken along lines A-A′, B-B′, and C-C′ of FIG. 2, respectively. FIGS. 6 and 7 are cross-sectional views taken along lines X1-X1′ and Y1-Y1′ of FIG. 2, respectively.

Referring to FIGS. 2 through 7, a semiconductor memory device 100A may include a substrate 101, an interlayer insulating film 102, a first conductive line 110, a first electrode layer 120, a first insulating structure 130, a first information storage film 140, a second conductive line 160, a second electrode layer 150, and a second insulating structure 170. In some embodiments, the substrate 101, the interlayer insulating film 102, the first conductive line 110, the first electrode layer 120, the first information storage film 140, the second electrode layer 150, and the second conductive line 160 may be sequentially stacked in a third direction Z that will be described below.

The substrate 101 may be a semiconductor substrate. For example, the substrate 101 may include a bulk silicon (Si) substrate or a silicon-on-insulator (SOI) substrate. The substrate 101 may include a Si substrate or may include another material, such as silicon germanium, indium antimonide, lead telluride, indium arsenide, indium phosphide, gallium arsenide, and/or gallium antimonide. In some embodiments, the substrate 101 may include an epitaxial layer formed on a base substrate.

The first conductive line 110 may be formed on the substrate 101. A plurality of first conductive lines 110 may be spaced apart from one another and may extend in parallel to one another.

Referring to FIG. 3, the first conductive lines 110 may extend in a first direction X, which is parallel to an upper surface of the substrate 101. The first conductive lines 110 may be spaced apart from one another in a second direction Y, which is parallel to the upper surface of the substrate 101 and intersects (e.g., perpendicular to) the first direction X. A plurality of first insulating structures 130 may be disposed between the first conductive lines 110, which are spaced apart from one another in the second direction Y.

The second conductive line 160 may be formed on the substrate 101. A plurality of second conductive lines 160 may be spaced apart from one another and may extend in parallel to one another. The second conductive lines 160 may intersect (e.g., overlap or cover) the first conductive lines 110. The second conductive lines 160 may be on an upper surface of the second electrode layer 150.

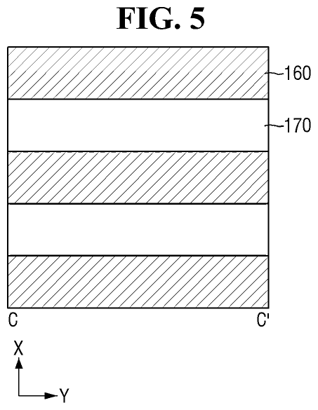

Referring to FIG. 5, the second conductive lines 160 may extend in the second direction Y. The second conductive lines 160 may be spaced apart from one another in the first direction X. A plurality of second insulating structures 170 may be disposed between the second conductive lines 160, which are spaced apart from one another in the first direction X. For example, the second insulating structures 170 and the second conductive lines 160 may be alternately arranged in the first direction X.

The first conductive lines 110 and the second conductive lines 160 may include, for example, tungsten (W), tungsten nitride (WN), gold (Au), silver (Ag), ruthenium (Ru), molybdenum (Mo), titanium (Ti), copper (Cu), aluminum (Al), titanium aluminum nitride (TiAlN), nickel (Ni), cobalt (Co), chromium (Cr), tin (Sn), zinc (Zn), and/or indium tin oxide (ITO), but the present disclosure is not limited thereto. The first conductive lines 110 and the second conductive lines 160 may include the same material or different materials. In some embodiments, the first conductive lines 110 and the second conductive lines 160 may include tungsten (W) and/or tungsten silicon nitride (WSiNₓ).

For example, the first conductive lines 110 may be wordlines (e.g., the wordlines WL in FIG. 1), and the second conductive lines 160 may be bitlines (e.g., the bitlines BL in FIG. 1). However, the present disclosure is not limited to this example. Alternatively, the first conductive lines 110 may be bitlines (e.g., the bitlines BL in FIG. 1), and the second conductive lines 160 may be wordlines (e.g., the wordlines WL in FIG. 1).

The first electrode layer 120 may extend in the first direction X. A plurality of first electrode layers 120 may be spaced apart from one another in the second direction Y. The second electrode layer 150 may extend in the second direction Y. A plurality of second electrode layers 150 may be spaced apart from one another in the first direction X.

The first electrode layers 120 may be interposed between the first conductive lines 110 and the first information storages film 140. The first electrode layers 120 may electrically connect the first conductive lines 110 and a plurality of first information storage films 140. The first electrode layers 120 may include, for example, a metal such as W, platinum (Pt), palladium (Pd), rhodium (Rh), Ru, iridium (Ir), Cu, Al, Ti, and/or tantalum (Ta), a metal nitride such as titanium nitride (TiN), and a combination thereof, but the present disclosure is not limited thereto. In some embodiments, the first electrode layers 120 may include, for example, a carbon (C) layer and/or a carbonitride (CN) layer.

A plurality of second electrode layers 150 may extend in the second direction Y and may be spaced apart from one another in the first direction X. The second electrode layers 150 may be interposed between the first information storage films 140 and the second conductive lines 160. The second electrode layers 150 may electrically connect the first information storage films 140 and the second conductive lines 160. The second electrode layers 150 may include, for example, a metal such as W, Pt, Pd, Rh, Ru, Ir, Cu, Al, Ti, and/or Ta, a metal nitride such as TiN, and/or a combination thereof, but the present disclosure is not limited thereto. In some embodiments, the second electrode layers 150 may include a C layer and/or a CN layer.

The interlayer insulating film 102 may be formed on (upper surface of) the substrate 101. A plurality of interlayer insulating films 102 may electrically isolate the first conductive lines 110 from one another. The interlayer insulating films 102 may include, for example, silicon oxide, silicon nitride, silicon oxynitride, and a combination thereof, but the present disclosure is not limited thereto.

A memory cell region MCR may be formed on the substrate 101 and the interlayer insulating films 102. The memory cell region MCR may electrically connect the first conductive lines 110 and the second conductive lines 160. For example, the memory cell region MCR may be between the first conductive lines 110 and the second conductive lines 160.

The first insulating structures 130 may (at least partially) fill first trenches TR1 in the memory cell region MCR. The first insulating structures 130 and the first conductive lines 110 may be alternately arranged in the second direction Y.

The first insulating structures 130 may extend in a third direction Z, which intersects (e.g., is perpendicular to) the first and second directions X and Y. For example, the third direction Z may be perpendicular to the upper surface of the substrate 101. The first insulating structures 130 may extend only partially into (e.g., partially penetrate) the first information storage films 140. The first information storage films 140 may not be (completely) separated from each other by the first insulating structures 130 in the second direction Y. The first insulating structures 130 may not completely penetrate the first information storage films 140 in the third direction Z.

The first insulating structures 130 may (at least partially) fill the spaces between the first conductive lines 110 and between the first electrode layers 120 in the memory cell region MCR.

A plurality of second insulating structures 170 may fill second trenches TR2 in the memory cell region MCR. The second insulating structures 170 may extend in the third direction Z and may thereby (at least partially) extend into (e.g., penetrate) the second conductive lines 160, the second electrode layers 150, and the first information storage films 140, on the first conductive lines 110. The first information storage films 140 may be separated from each other by the second insulating structures 170 in the first direction X. The second insulating structures 170 and the second conductive lines 160 may be alternately arranged in the first direction X. The second insulating structures 170 may not extend into (e.g., penetrate) the first electrode layers 120 in the third direction Z.

Each of the first insulating structures 130 and the second insulating structures 170 may include, for example, a silicon oxide film, a silicon nitride film, and/or a combination thereof. In some embodiments, the first insulating structures 130 and the second insulating structures 170 may include seams or air gaps. In some embodiments, the term “air” may refer to gases that can be present in the atmosphere or during the manufacturing process.

The first information storage films 140 may include a material whose resistance can changes according to the magnitude of a voltage applied to both (e.g., opposite) ends thereof. The first information storage film 140 may include, for example, an ovonic threshold switching (OTS) material.

The first information storage films 140 may include, for example, germanium (Ge), arsenic (As), and/or selenium (Se) and may further include, for example, silicon (Si), indium (In), tellurium (Te), tin (Sn), gallium (Ga), and/or nitrogen (N). For example, the first information storage films 140 may include at least two of Ge, As, and Se.

In some embodiments, the first information storage films 140 may be controlled to have different threshold voltages during a normal operation of the semiconductor memory device 100A. For example, chalcogenide contained in the first information storage film 140 may have first and second threshold voltages, which are different from each other, according to a bias applied to the first information storage films 140. The first threshold voltage may correspond to a first logic state of data storage elements, for example, a logic value of 0, and the second threshold voltage may correspond to a second logic state of data storage elements, for example, a logic value of 1. The difference between the first and second threshold voltages may be defined as the read window margin (RWM) of the semiconductor memory device 100A. The semiconductor memory device 100A including the information storage films 140 may be provided as a selector-only memory (SOM) or a self-selecting memory (SSM).

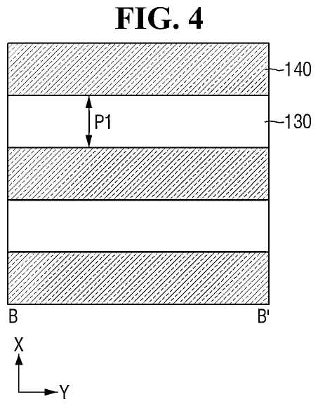

Referring to FIGS. 4 and 6, a spacing P1 of the first information storage films 140 in the first direction X may be 10 nm to 40 nm, but the present disclosure is not limited thereto.

A thickness T1 of the first information storage film 140 in the third direction Z may be three times or less than a width W1 of the first information storage film 140 in the first direction X. For example, the thickness T1 of the first information storage film 140 in the third direction Z may be, but is not limited to, 60 nm or less, and the width W1 of the first information storage film 140 in the first direction X may be, but is not limited to, 20 nm.

Referring to FIG. 7, a thickness H1 of the first information storage film 140 in the third direction Z may be, but is not limited to, about 5 nm to 40 nm. A height H2 from an upper surface of the first electrode layer 120 to an upper surface of the first insulating structure 130 in the third direction Z may be, but is not limited to, 1 nm to 60 nm.

The upper surface of the first electrode layer 120 may have a different height from the upper surface of the first insulating structure 130 in the third direction Z. That is, a step may be formed between the upper surface of the first electrode layer 120 and the upper surface of the first insulating structure 130. The upper surface of the first insulating structure 130 may protrude beyond (above, upward, or higher than) the upper surface of the first electrode layer 120 in the third direction Z. Spatially relative terms, such as “beneath,” “below,” “lower,” “above,” “upper,” “higher” and the like, may be used herein for ease of description to describe one element or feature's relationship to another element(s) or feature(s) as illustrated in the figures. For example, a height of element A may refer to a distance of element A from an upper surface of the substrate 101 in the third direction Z. It will be understood that the spatially relative terms are intended to encompass different orientations of the device in use or operation in addition to the orientation depicted in the figures. For example, if a device in the figures is turned over, elements described as “below” or “beneath” other elements or features would then be oriented “above” the other elements or features. Thus, the term “below” can encompass both an orientation of above and below. The device may be otherwise oriented (e.g., rotated 90 degrees or at other orientations) and the spatially relative descriptors used herein may be interpreted accordingly.

The first information storage film 140 may include a first region R1, which is adjacent to the first conductive line 110, and a second region R2, which is adjacent to the first insulating structure 130. For example, the first region R1 may overlap the first conductive line 110 in the third direction Z, and the second region R2 may overlap the first insulating structure 130 in the third direction Z. The first regions R1 may correspond to portions of the first information storage film 140 that correspond to the first conductive lines 110, and the second regions R2 may be portions of the first information storage film 140 that correspond to the first insulating structures 130. The first region(s) R1 and the second region(s) R2 may be connected to each other in the second direction Y. As used herein, “an element A overlapping an element B in a direction X” (or similar language) means that there is at least one line that extends in the direction X and intersects both the elements A and B.

As the step is formed, a height SH1 of the upper surface of the first region R1 in the third direction Z may be different from a height SH2 of the upper surface of the second region R2 in the third direction Z. The height SH1 of the upper surface of the first region R1 in the third direction Z may be less than the height SH2 of the upper surface of the second region R2 in the third direction Z.

Accordingly, height differences may also be generated on a lower surface of the second electrode layer 150, which is in contact with the upper surface of the first information storage film 140. That is, the height of the lower surface of the second electrode layer 150 in the first region R1, near the first conductive line 110 (e.g., overlapping the first conductive line 110 in the third direction Z), may be different from the height of the lower surface of the second electrode layers 150 in the second region R2, near the first insulating structure 130 (e.g., overlapping the first insulating structure 130 in the third direction Z).

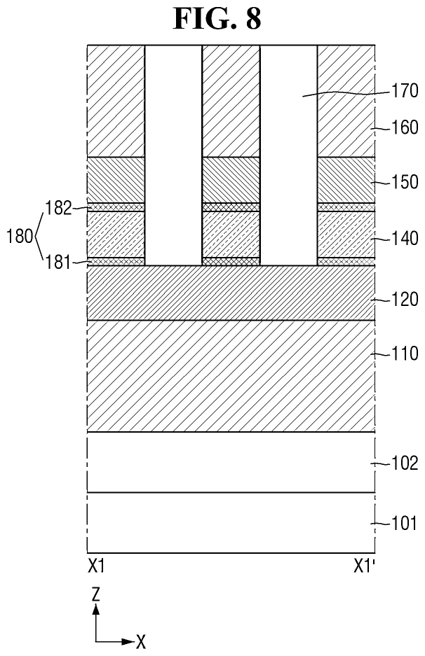

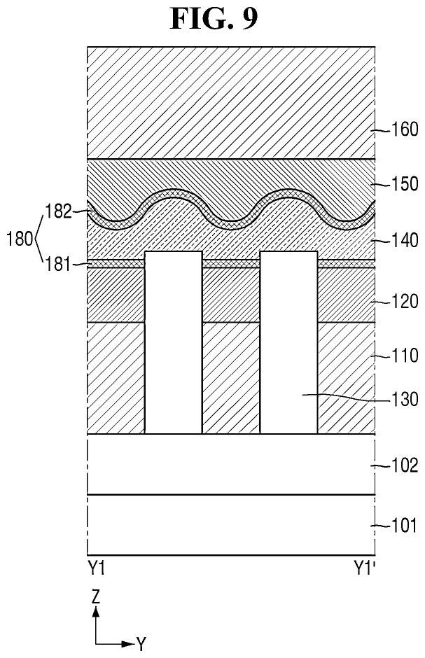

FIGS. 8 and 9 are cross-sectional views of a semiconductor memory device according to some embodiments of the present disclosure. For convenience, redundant or repetitive portions that overlap with the content described earlier with reference to FIGS. 1 through 7 may be briefly mentioned or omitted. Specifically, FIGS. 8 and 9 are cross-sectional views taken along lines X1-X1′ and Y1-Y1′ of FIG. 2, respectively.

Referring to FIGS. 8 and 9, in some embodiments, the semiconductor memory device according to some embodiments of the present disclosure may further include a barrier structure 180. The barrier structure 180 may include a first barrier layer 181 and a second barrier layer 182.

A plurality of first barrier layers 181 may be spaced apart from one another in the first and second directions X and Y between the first conductive lines 110 and the first information storage films 140. A plurality of second barrier layers 182 may extend in the second direction Y between the second conductive lines 160 and the first information storage films 140 and may be spaced apart from one another in the first direction X. The first information storage films 140 may be interposed between the first barrier layers 181 and the second barrier layers 182.

The height of an upper surface of the second barrier layer 182 near the first conductive lines 110 (e.g., overlapping the first conductive line 110 in the third direction Z) may be different from the height of an upper surface of the second barrier layer 182 near first insulating structures 130 (e.g., overlapping the first insulating structure 130 in the third direction Z).

The first barrier layer 181 and the second barrier layer 182 may include a conductive material, for example, W, WN, WC, and/or a combination thereof, but the present disclosure is not limited thereto.

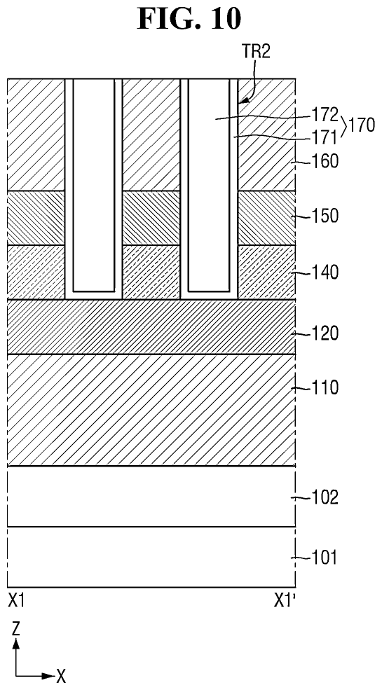

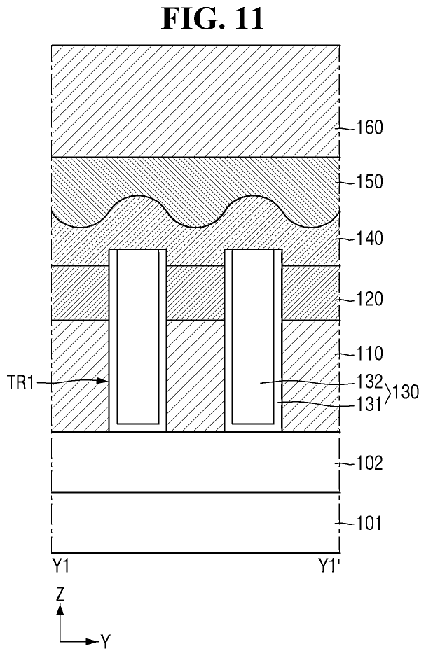

FIGS. 10 and 11 are cross-sectional views of a semiconductor memory device according to some embodiments of the present disclosure. For convenience, redundant or repetitive portions that overlap with the content described earlier with reference to FIGS. 1 through 7 may be briefly mentioned or omitted. Specifically, FIGS. 10 and 11 are cross-sectional views taken along lines X1-X1′ and Y1-Y1′ of FIG. 2, respectively.

Referring to FIGS. 10 and 11, in some embodiments, the first insulating structure 130 may include a first liner film 131 and a first gap-fill insulating film 132, and the second insulating structure 170 may include a second liner film 171 and a second gap-fill insulating film 172.

The first liner film 131 may be formed along the sidewalls and lower surface of the first trench TR1. The first gap-fill insulating film 132 may be disposed on the first liner film 131 and may (at least partially) fill the remaining portion of the first trench TR1.

The second liner film 171 may be formed along the sidewalls and lower surface of the second trench TR2. The second gap-fill insulating film 172 may be disposed on the second liner film 171 and may (at least partially) fill the remaining portion of the second trench TR2.

The first liner film 131, the first gap-fill insulating film 132, the second liner film 171, and the second gap-fill insulating film 172 may include, for example, silicon oxide, silicon nitride, and/or a combination thereof.

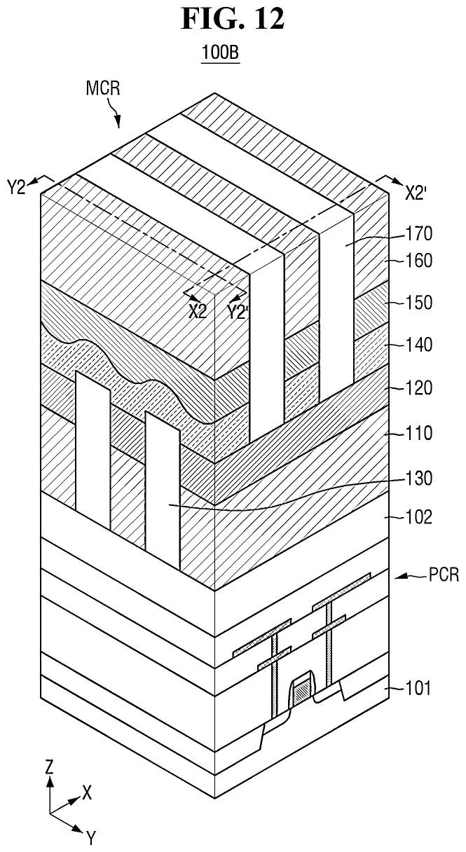

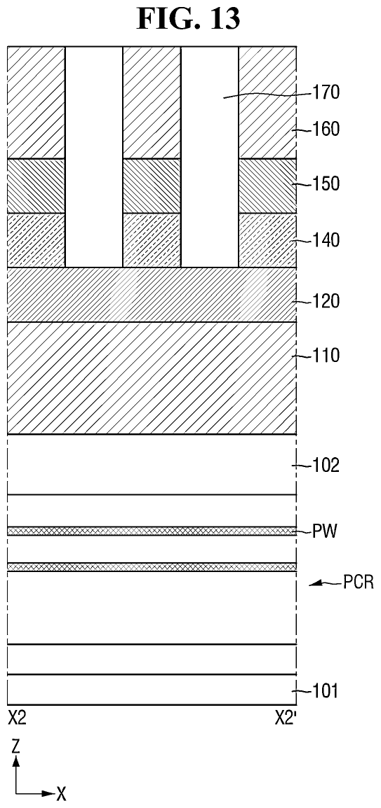

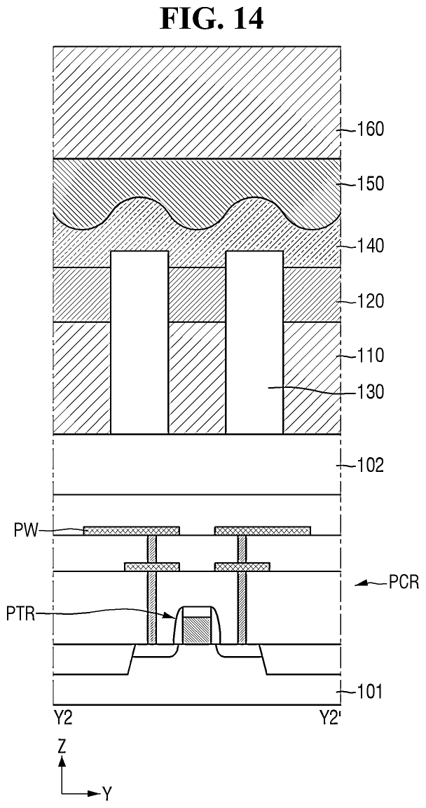

FIG. 12 is a perspective view of a semiconductor memory device according to some embodiments of the present disclosure. FIGS. 13 and 14 are cross-sectional views taken along lines X2-X2′ and Y2-Y2′ of FIG. 12, respectively. For convenience, redundant or repetitive portions that overlap with the content described earlier with reference to FIGS. 1 through 7 may be briefly mentioned or omitted.

Referring to FIGS. 12 through 14, a semiconductor memory device 100B may further include a peripheral circuit region PCR below the memory cell region MCR, and the peripheral circuit region PCR may include a peripheral transistor PTR and peripheral wiring PW.

The peripheral circuit region PCR may be disposed between the substrate 101 and the interlayer insulating film 102.

The peripheral circuit region PCR may include peripheral circuits or driving circuits for driving the memory cell region MCR. The peripheral circuit region PCR may include circuits capable of processing data input to or output from the memory cell region MCR at high speed. The peripheral circuit region PCR may include the peripheral circuit 30 of FIG. 1. The peripheral circuit region PCR may include, for example, a page buffer, a latch circuit, a cache circuit, a sense amplifier, a data in/out circuit, etc.

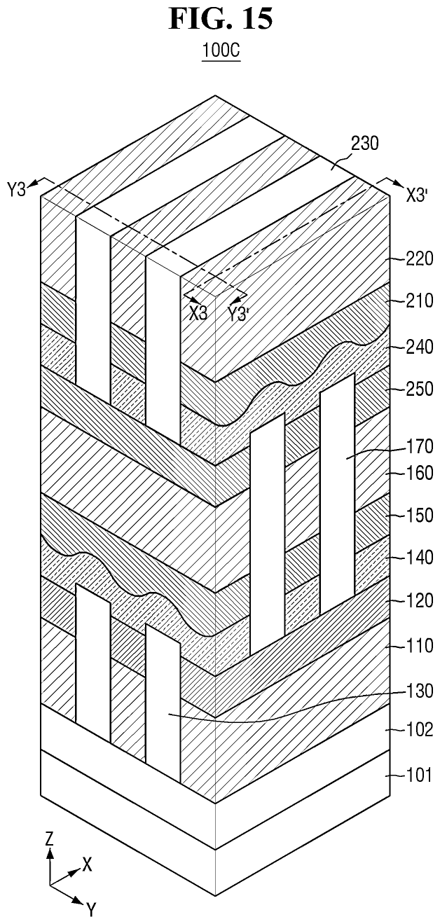

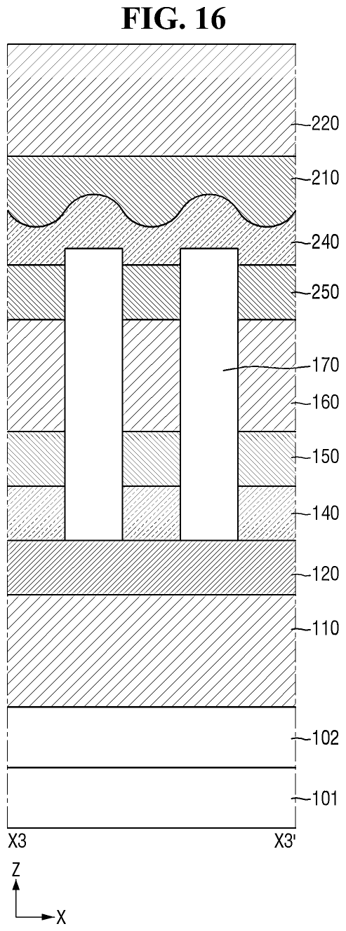

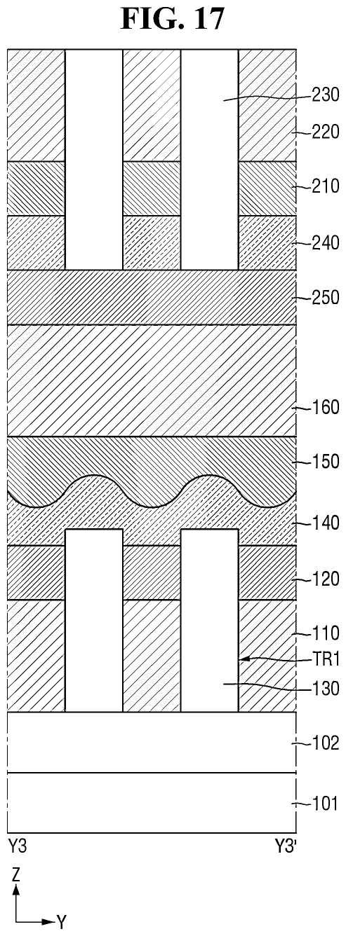

FIG. 15 is a perspective view of a semiconductor memory device according to some embodiments of the present disclosure. FIGS. 16 and 17 are cross-sectional views taken along lines X3-X3′ and Y3-Y3′ of FIG. 15, respectively. For convenience, redundant or repetitive portions that overlap with the content described earlier with reference to FIGS. 1 through 7 may be briefly mentioned or omitted.

Referring to FIGS. 15 through 17, a semiconductor memory device 100C may further include a third electrode layer 250, a second information storage film 240, a fourth electrode layer 210, a third conductive line 220, and a third insulating structure 230. In some embodiments, the third electrode layer 250, the second information storage film 240, the fourth electrode layer 210, and the third conductive line 220 may be stacked sequentially in the third direction Z.

The third electrode layer 250 may be formed on the second conductive line 160. A plurality of third electrode layers 250 may be spaced apart from one another and may extend in parallel to one another. The third electrode layers 250 may extend in the second direction Y. The third electrode layers 250 may be spaced apart from one another in the first direction X. The second insulating structures 170 may be disposed between the third electrode layers 250, which are spaced apart from one another in the first direction X. For example, the second insulating structures 170 may be alternately arranged with the third electrode layers 250 in the first direction X.

The second information storage film 240 may extend in the first direction X on the third electrode layer 250 and the second conductive lines 160. A plurality of second information storage films 240 may be spaced apart from one another in the second direction Y.

The second information storage film 240 may include a material whose resistance can changes according to the magnitude of a voltage applied to both (e.g., opposite) ends thereof. The second information storage film 240 may include, for example, an OTS material.

The second information storage film 240 may include, for example, Ge, As, and/or Se and may further include, for example, Si, In, Te, Sn, Ga, and/or N.

The fourth electrode layer 210 may be formed on the second information storage film 240. A plurality of fourth electrode layers 210 may be spaced apart from one another and may extend in parallel to one another. The fourth electrode layers 210 may extend in the first direction X. The fourth electrode layers 210 may be spaced apart from one another in the second direction Y. A plurality of third insulating structures 230 may be disposed between the fourth electrode layers 210, which are spaced apart from one another in the second direction Y. For example, the third insulating structures 230 may be alternately arranged with the fourth electrode layers 210 in the second direction Y.

The third electrode layer 250 and the fourth electrode layer 210 may include, for example, a metal such as W, Pt, Pd, Rh, Ru, Ir, Cu, Al, Ti, and/or Ta, a metal nitride such as TiN, and/or a combination thereof, but the present disclosure is not limited thereto. In some embodiments, each of the third electrode layer 250 and the fourth electrode layer 210 may include, for example, a C layer and/or a CN layer.

The third conductive line 220 may be formed on the second information storage film 240 and the fourth electrode layer 210. A plurality of third conductive lines 220 may be spaced apart from one another and may extend in parallel to one another. The third conductive lines 220 may extend in the first direction X. The third conductive lines 220 may be spaced apart from one another in the second direction Y. The third insulating structures 230 may be disposed between the third conductive lines 220, which are spaced apart from one another in the second direction Y. For example, the third insulating structures 230 may be alternately arranged with the third conductive lines 220 in the second direction Y.

The third conductive line 220 may include, for example, W, WN, Au, Ag, Ru, Mo, Ti, Cu, Al, TiAlN, Ni, Co, Cr, Sn, Zn, and/or ITO, but the present disclosure is not limited thereto. In some embodiments, the third conductive line 220 may include, for example, W and/or tungsten silicon nitride (WSiNₓ).

The third insulating structure 230 may extend in the third direction Z to at least partially extend into (at least partially penetrate) the second information storage films 240, the fourth electrode layers 210, and the third conductive lines 220. The first insulating structure 130 may not completely penetrate the first information storage film 140 in the third direction Z, and the second insulating structure 170 may not completely penetrate the second information storage film 240 in the third direction Z.

The height of an upper surface of the third electrode layer 250 in the third direction Z may be different from the height of an upper surface of the second insulating structure 170 in the third direction Z. That is, a step may be formed between the upper surface of the third electrode layer 250 and the upper surface of the second insulating structure 170. The upper surface of the second insulating structure 170 may protrude beyond (above, upward, or higher than) the upper surface of the third electrode layer 250 in the third direction Z. The second insulating structure 170 may extend only partially extend into the second information storage film 240 in the third direction Z.

As the step is formed, the height of the upper surface of the second information storage film 240 near the second conductive line 160 (e.g., overlapping the second conductive line 160 in the third direction Z) may be different from the height of the upper surface of the second information storage film 240 near the second insulating structure 170 (e.g., overlapping the second insulating structure 170 in the third direction Z). The height of the upper surface of the second information storage film 240 near the second conductive line 160 (e.g., overlapping the second conductive line 160 in the third direction Z) may be less than the height of the upper surface of the second information storage film 240 near the second insulating structure 170 (e.g., overlapping the second insulating structure 170 in the third direction Z).

Accordingly, height differences may also be generated on a lower surface of the fourth electrode layer 210, which is in contact with the upper surface of the second information storage films 240. That is, the height of the lower surface of the fourth electrode layer 210 near the second conductive line 160 (e.g., overlapping the second conductive line 160 in the third direction Z) may be different from the height of the lower surface of the fourth electrode layer 210 near the second insulating structure 170 (e.g., overlapping the second insulating structure 170 in the third direction Z).

Although not specifically depicted, an interlayer insulating film may be additionally disposed on the third conductive line 220. The interlayer insulating film may be interposed between conductive lines of a semiconductor memory device in an array form. The interlayer insulating film may include, for example, an oxide film, a nitride film, and/or a combination thereof, but the present disclosure is not limited thereto.

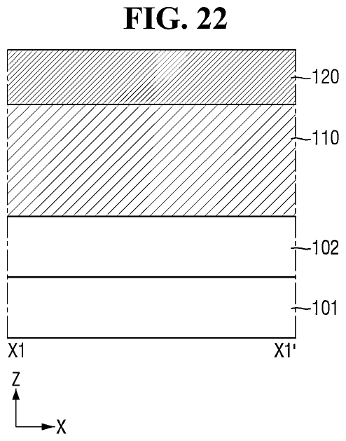

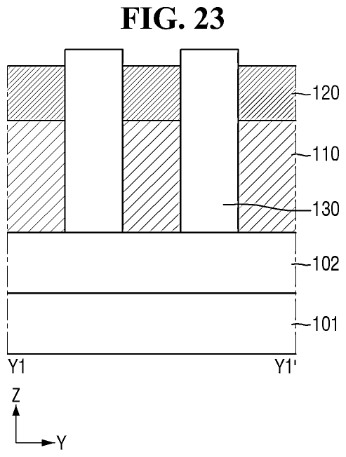

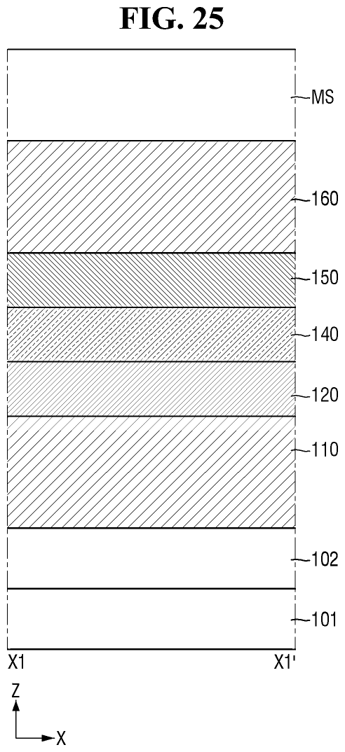

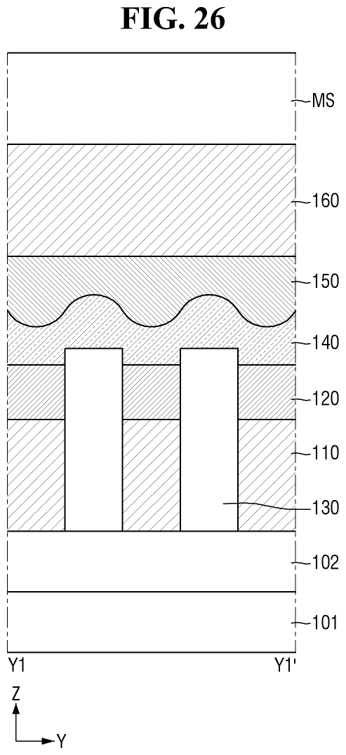

A method of fabricating a semiconductor memory device according to some embodiments of the present disclosure will hereinafter be described with reference to FIGS. 1 through 7 and 18 through 28.

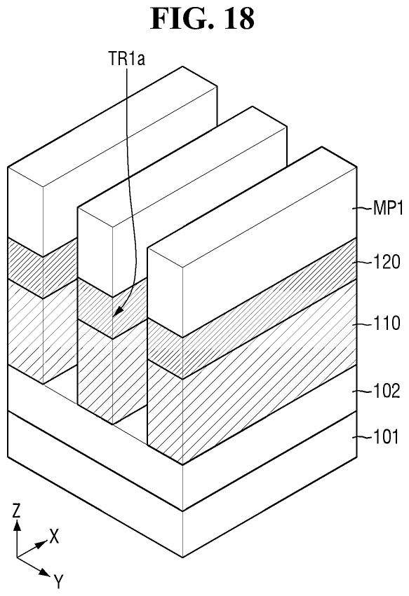

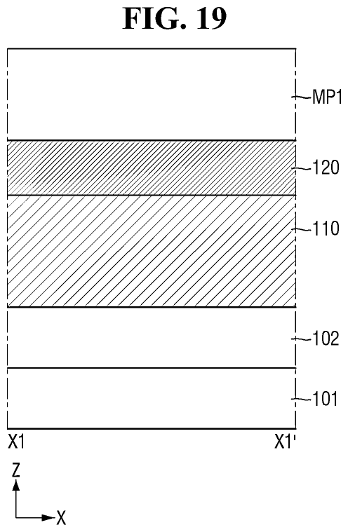

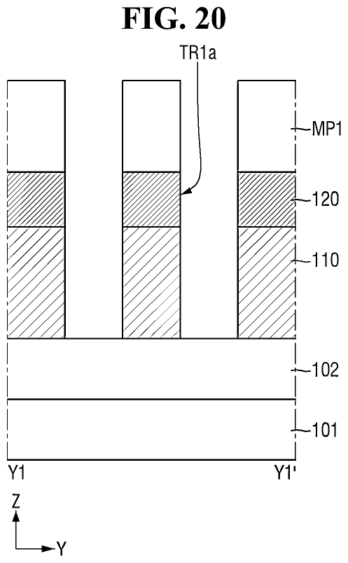

FIGS. 18 through 28 illustrate intermediate steps of a method of fabricating a semiconductor memory device according to some embodiments of the present disclosure. For convenience, redundant or repetitive portions that overlap with the content described earlier with reference to FIGS. 1 through 7 may be briefly mentioned or omitted. Specifically, FIGS. 19, 22, 25, and 28 are cross-sectional views taken along line X1-X1′ of FIG. 2. FIGS. 20, 23, and 26 are cross-sectional views taken along line Y1-Y1′ of FIG. 2.

Referring to FIGS. 18 through 20, the interlayer insulating film 102 may be formed on the substrate 101, the first conductive line 110 and the first electrode layer 120 may be formed on the interlayer insulating film 102, and a mask layer may be formed on the first electrode layer 120.

Thereafter, by patterning the mask layer, the plurality of first conductive lines 110, the plurality of first electrode layers 120, and plurality of first mask patterns MP1, which all extend in a first direction X and are spaced apart from one another in a second direction Y, may be formed.

In this case, an etching process may be performed on a second conductive line 160 and a second electrode layer 150 in the first direction X. That is, the etching process may not be performed on a first information storage film 140 in the first direction X.

The first conductive lines 110, the first electrode layers 120, and the first mask patterns MP1 may be spaced apart from one another by 1a-th trenches TR1a in the second direction Y. The patterning of the mask layer may be performed using, for example, a typical photolithography process.

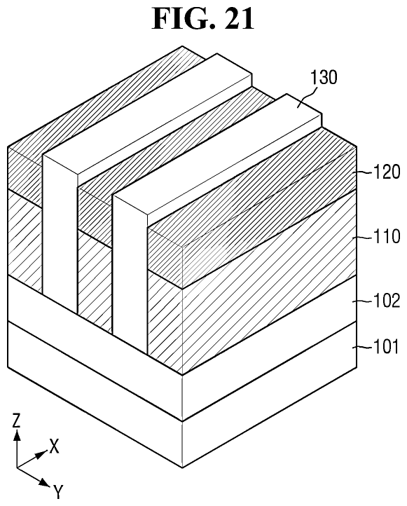

Referring to FIGS. 21 through 23, a plurality of first insulating structures 130, which (at least partially) fill the 1a-th trenches TR1a, may be formed. Thereafter, the first mask patterns MP1 may be removed, and an etch-back process may be performed by performing a chemical mechanical polishing (CMP) process or an ashing process using oxygen on the upper surfaces of the first insulating structures 130 and the upper surfaces of the first electrode layers 120.

In a case where a CMP process is performed on the upper surfaces of the first insulating structures 130 and the upper surfaces of the first electrode layers 120, the selectivity during node separation of the first conductive lines 110 can be adjusted to form protruding first insulating structures 130.

In a case where an etch-back process is performed on the upper surfaces of the first insulating structures 130 and the upper surfaces of the first electrode layers 120, the etching selectivity between the first electrode layers 120 and the first insulating structures 130 can be adjusted to form first insulating structures 130 that protrude beyond (above, upward, or higher than) the first electrode layers 120.

Accordingly, the steps may be formed between the upper surfaces of the first insulating structures 130 and the upper surfaces of the first electrode layers 120. Due to the steps, the upper surfaces of the first information storage film 140 near the first conductive lines 110 (e.g., overlapping the first conductive lines 110 in the third direction Z) may have a different height from the upper surfaces of the first information storage film 140 near the first insulating structures 130 (e.g., overlapping the first insulating structures 130 in the third direction Z).

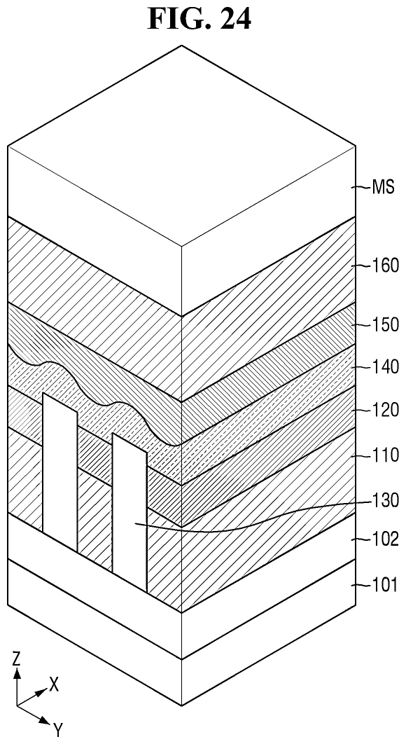

Referring to FIGS. 24 through 26, the first information storage film 140, the second electrode layer 150, the second conductive line 160, and a mask layer MS may be sequentially stacked on the upper surfaces of the first insulating structures 130 and the upper surfaces of the first electrode layers 120.

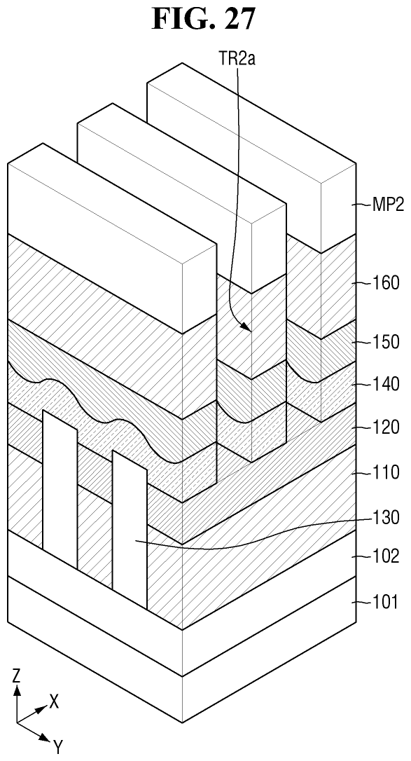

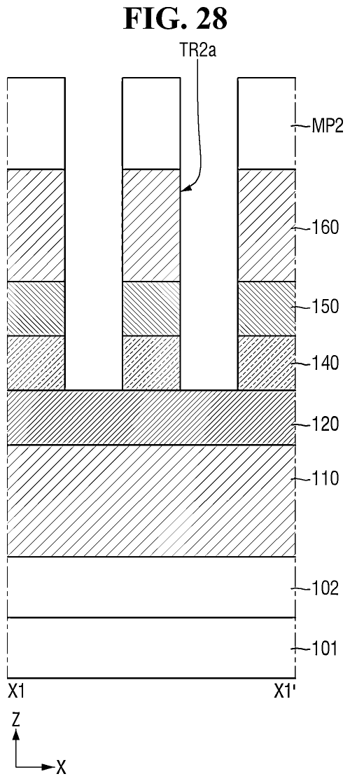

Referring to FIGS. 27 and 28, by patterning the mask layer MS, second conductive lines 160, second electrode layers 150, first information storage films 140, and second mask patterns MP2, which all extend in the second direction Y, may be formed. In this case, an etching process may be performed on the single second conductive line 160, the single second electrode layer 150, and the single first information storage film 140 in the second direction Y.

The second conductive lines 160, the second electrode layers 150, the first information storage films 140, and the second mask patterns MP2 may be spaced apart from one another by 2a-th trenches TR2a in the first direction X. The patterning of the mask layer MS may be performed using, for example, a typical photolithography process.

Thereafter, a plurality of second insulating structures 170, which at least partially fill the 2a-th trenches TR2a, may be formed. Thereafter, the second mask patterns MP2 may be removed, and a CMP process may be performed such that the upper surfaces of the second insulating structures 170 and the upper surfaces of the second conductive lines 160 may be positioned on the same plane.

As a result, the semiconductor memory device of FIGS. 1 through 7 can be obtained.

According to some embodiments, an etching process may be performed only in the second direction Y and not in the first direction X on the first information storage films 140 with OTS characteristics. As a result, damage to the first information storage films 140 caused by chemical substances and similar factors during the etching process can be minimized. Therefore, as depicted in FIGS. 2 and 7, the first information storage films 140 can be structured to be separated only in the first direction X and not in the second direction Y.

However, if the first information storage films 140 are formed in a linear shape without being separated in the second direction Y, adjacent wordlines (e.g., the wordlines WL in FIG. 1) can concentrate the electric field, resulting in reduced device reliability.

In some embodiments, during the aforementioned CMP or etching process, the height of the upper surfaces of the first insulating structures 130 can be formed higher than the first conductive lines 110 and/or the first electrode layers 120. Consequently, the height of the upper surfaces of the first information storage films 140 near the first conductive lines 110 (e.g., overlapping the first conductive lines 110 in the third direction Z) can be lowered, thereby preventing the aforementioned issue related to electric field concentration.

Embodiments of the present disclosure have been described above with reference to the accompanying drawings, but the present disclosure is not limited thereto and may be implemented in various different forms. It will be understood that the present disclosure can be implemented in other specific forms without changing the technical spirit or gist of the present disclosure. Therefore, it should be understood that the embodiments set forth herein are illustrative in all respects and not limiting.

What is claimed is:

1. A semiconductor memory device comprising:
a substrate that extends in a first direction and a second direction, wherein the first direction and the second direction intersect each other;
first conductive lines that extend in the first direction on the substrate;
first insulating structures that are alternately arranged with the first conductive lines in the second direction, wherein the first insulating structures extend in a third direction that intersects the first direction and the second direction;
first information storage films on the first conductive lines and the first insulating structures; and
second conductive lines that extend in the second direction on the first information storage films,
wherein
the first direction and the second direction are parallel with an upper surface of the substrate,
the third direction is perpendicular to the upper surface of the substrate,
the first information storage films include first regions that overlap the first conductive lines in the third direction, and second regions that overlap the first insulating structures in the third direction, and
a first height of upper surfaces of the first regions is different from a second height of upper surfaces of the second regions.

2. The semiconductor memory device of claim 1, wherein the first information storage films are spaced apart from one another in the first direction, and
the first regions and the second regions are connected to each other in the second direction.

3. The semiconductor memory device of claim 1, further comprising:
first electrode layers on the first conductive lines, wherein the first electrode layers extend in the first direction and are spaced apart from one another in the second direction; and
second electrode layers on the first information storage films, wherein the second electrode layers extend in the second direction and are spaced apart from one another in the first direction.

4. The semiconductor memory device of claim 1, wherein the first insulating structures partially extend into the first information storage films.

5. The semiconductor memory device of claim 1, further comprising:
second insulating structures that extend in the third direction on the first conductive lines, wherein the second insulating structures extend into the second conductive lines and the first information storage films.

6. The semiconductor memory device of claim 1, further comprising:
first barrier layers that are spaced apart from one another in the first direction and the second direction between the first conductive lines and the first information storage films; and
second barrier layers that extend in the second direction and are spaced apart from one another in the first direction, between the second conductive lines and the first information storage films.

7. The semiconductor memory device of claim 6, wherein a third height of upper surfaces of the second barrier layers that overlap the first conductive lines in the third direction is different from a fourth height of upper surfaces of the second barrier layers that overlap the first insulating structures in the third direction.

8. The semiconductor memory device of claim 1, further comprising:
second information storage films on the second conductive lines, wherein the second information storage films extend in the first direction and are spaced apart from on another in the second direction;
third conductive lines on the second information storage films, wherein the third conductive lines extend in the first direction and are spaced apart from one another in the second direction; and
third insulating structures on the second conductive lines, wherein the third insulating structures extend into the third conductive lines and the second information storage films.

9. The semiconductor memory device of claim 1, wherein a thickness of the first information storage films in the third direction is three times or less than a width of the first information storage films in the first direction.

10. The semiconductor memory device of claim 1, wherein the first information storage films include germanium (Ge), arsenic (As), selenium (Se), indium (In), tellurium (Te), tin (Sn),
gallium (Ga), silicon (Si), and/or nitrogen (N).

11. A semiconductor memory device comprising:
a substrate that extends in a first direction and a second direction, wherein the first direction and the second direction intersect each other;
first conductive lines that extend in the first direction on the substrate;
first insulating structures that are alternately arranged with the first conductive lines in the second direction, wherein the first insulating structures extend in a third direction that intersects the first direction and the second direction;
first information storage films on the first conductive lines and the first insulating structures;
second conductive lines that extend in the second direction on the first information storage films; and
second insulating structures that are alternately arranged with the second conductive lines in the first direction, wherein the second insulating structures extend into the first information storage films in the third direction,
wherein the first direction and the second direction are parallel with an upper surface of the substrate,
the third direction is perpendicular to the upper surface of the substrate,
a first height of upper surfaces of the first information storage films that overlap the first conductive lines in the third direction is different from a second height of upper surfaces of the first information storage films that overlap the first insulating structures in the third direction, and
the first information storage films continuously extend in the second direction, and are separated by the second insulating structures in the first direction.

12. The semiconductor memory device of claim 11, wherein a third height of upper surfaces of the first conductive lines in the third direction is different from a fourth height of upper surfaces of the first insulating structures in the third direction.

13. The semiconductor memory device of claim 11, wherein a fifth height of upper surfaces of the second conductive lines in the third direction is different from a sixth height of upper surfaces of the second insulating structures in the third direction.

14. The semiconductor memory device of claim 11, further comprising:
second information storage films on the second conductive lines and the second insulating structures, wherein the second information storage films extend in the first direction and are spaced apart from one another in the second direction.

15. The semiconductor memory device of claim 14, wherein a seventh height of upper surfaces of the second information storage films that overlap the second conductive lines in the third direction is different from an eighth height of upper surfaces of the second information storage films that overlap the second insulating structures in the third direction.

16. The semiconductor memory device of claim 11, further comprising:
first electrode layers on the first conductive lines, wherein the first electrode layers extend in the first direction and are spaced apart from one another in the second direction; and
second electrode layers on the first information storage films, wherein the second electrode layers extend in the second direction and are spaced apart from one another in the first direction,
wherein the second electrode layers are between the second conductive lines and the first information storage films,
the first electrode layers and the second electrode layers include carbon, and
the first conductive lines and the second conductive lines include tungsten (W), ruthenium (Ru), molybdenum (Mo), titanium (Ti), and/or copper (Cu).

17. A semiconductor memory device comprising:
a substrate that extends in a first direction and a second direction, wherein the first direction and the second direction intersect each other;
first conductive lines that extend in the first direction on the substrate;
first insulating structures that are alternately arranged with the first conductive lines in the second direction, wherein the first insulating structures extend in a third direction that intersects the first direction and the second direction;
first information storage films on the first conductive lines and the first insulating structures;
second conductive lines that extend in the second direction on the first information storage films;
second insulating structures that are alternately arranged with the second conductive lines in the first direction, wherein the second insulating structures extend into the first information storage films in the third direction;
second information storage films on the second conductive lines and the second insulating structures, wherein the second information storage films extend in the first direction and are spaced apart from one another in the second direction;
third conductive lines that extend in the first direction on the second information storage films; and
third insulating structures that are alternately arranged with the third conductive lines in the second direction and extend into the third conductive lines and the second information storage films,
wherein the first direction and the second direction are parallel with an upper surface of the substrate,
the third direction is perpendicular to the upper surface of the substrate,
first steps are disposed between upper surfaces of the first conductive lines and upper surfaces of the first insulating structures, and
the first insulating structures partially extend into the first information storage films in the third direction.

18. The semiconductor memory device of claim 17, wherein
second steps are disposed between to upper surfaces of the second conductive lines and upper surfaces of the second insulating structures, and
the second insulating structures partially extend into the second information storage films in the third direction.

19. The semiconductor memory device of claim 17, wherein
a first height of upper surfaces of the first information storage films that overlap the first conductive lines in the third direction is different from a second height of upper surfaces of the first information storage films that overlap the first insulating structures in the third direction, and
a third height of upper surfaces of the second information storage films that overlap the second conductive lines in the third direction is different from a fourth height of upper surfaces of the second information storage films that overlap the second insulating structures in the third direction.

20. The semiconductor memory device of claim 17, further comprising:
first electrode layers on the first conductive lines, wherein the first electrode layers extend in the first direction and are spaced apart from one another in the second direction;
second electrode layers on the first information storage films, wherein the second electrode layers extend in the second direction and are spaced apart from one another in the first direction;
third electrode layers on the second conductive lines, wherein the third electrode layers extend in the second direction and are spaced apart from one another in the first direction; and
fourth electrode layers on the second information storage films, wherein the fourth electrode layers extend in the first direction and are spaced apart from one another in the second direction,
wherein
a fifth height of lower surfaces of the second electrode layers that overlap the first conductive lines in the third direction is different from a sixth height of lower surfaces of the second electrode layers that overlap the first insulating structures in the third direction, and
a seventh height of lower surfaces of the fourth electrode layers that overlap the second conductive lines in the third direction is different from a eighth height of lower surfaces of the fourth electrode layers that overlap the second insulating structures in the third direction.
